(19) United States
(12) Patent Application Publication
(10) Pub. No.: US 2002/0067518 A1
(43) Pub. Date: Jun. 6, 2002

(54) Process and apparatus for the manufacture of a digital color picture

(76) Inventors: Christian Benz, Unterehrendingen (CH); Arthur Muhlemann, Wetzikoh (CH); Thorsten Braun, Rheine (DE)

Correspondence Address: Patrick C. Keane, BURNS DOANE, SWECKER & MATHIS, L.L.P., P.O. Box 1404, Alexandria, VA, 22313-1404, US

(21) Appl. No.: 09/940,666

(22) Filed: Aug. 29, 2001

(30) Foreign Application Priority Data
Aug. 30, 2000 (EP) 00 118 169.2

(51) Int. Cl. G03F 3/08

(52) U.S. Cl. 358/518

(57) ABSTRACT

A photographic original is photoelectrically scanned by way of a color-enabled scanning device for the manufacture of a digital color picture and a raw digital color picture is thereby formed from the scanning data obtained. The final digital color picture is formed by way of a color transformation of the raw color picture according to the principles of color management, whereby a device specific profile is used which describes the combination of the type specific calorimetric properties of the original and the transfer function of the scanning device used, with respect to an analog manufactured reference color picture. The different types of originals occurring in practice are assigned to categories according to calorimetric similarity criteria and a master original is selected in each category. Profiles are respectively created only for the master original. Depending on the quality required, different category assignments and selections of original type of master originals can be made. All original types of one category are processed using the same profile belonging to the master original of the category. A true color digital image reproduction is achieved independent of the actual type of original used and the actual type of scanner used by inclusion of the color management into the manufacturing process of the digital color picture. The use of original type categories keeps the cost within practical limits.

### FIELD OF THE INVENTION

The invention relates to a process and apparatus for the manufacture of a digital color picture, especially from a photographic original.

### BACKGROUND ART

It is a growing trend in the image processing industry to provide color pictures from any original, not only in the classical form as physical color prints (so called analog color photos) but additionally or alternatively also digitally in the form of image files (for example in JPEG format). For the manufacture of the latter, the original is digitized by way of a high resolution, color-enabled photoelectric scanning device (scanner) and a digital image file is built from the scanning data obtained, possibly after an image conversion (negative to positive), and recorded on a suitable data carrier medium, for example a compact disk. The image file can then be displayed on a screen by way of conventional imaging software and possibly also printed out on a color printer.

Experience has shown that the color impression generally significantly differs between analog and digital color pictures made from the same original, even when an optimally calibrated display screen is used. This is caused by the multitude of different types of originals (different name brands and types of negatives or positives) which must be processed and by the different color properties (transfer functions) of the devices involved in the image production. For example, it is practically impossible to adjust the scanner in such a way that it always delivers the same result independent of the original used and, conversely, different brand scanners produce different color image files for exactly the same type of original, even when optimally calibrated.

### SUMMARY OF THE INVENTION

It is now an object of the invention to provide a method for the production of digital color pictures of a high quality, realistic and consistent reproduction largely independent of the type of original and the scanning device used. The level of quality achieved for digitally produced color pictures should thereby be equal to the level of quality achieved or selected by the processing photo lab (photo finishing enterprise, or specialized lab, or pre-press studio, or the like) for analog, which means classically manufactured, physical color prints. It is a further goal of the present invention to provide the prerequisites for largely automatically maintaining the quality of the color reproduction in digital production processes constant, which means without manual corrective intervention which disrupts the production flow.

This object is achieved in accordance with the present invention in a process for the manufacture of a digital color picture from an original, preferably a photographic original, in which the original is scanned by way of a color enabled scanning device and the digital color picture is produced from the scanning data obtained. The raw digital color image data produced by the scanner are subjected to a color transformation according to color management methods prior to storage or registration. The transformation considers the type-specific colormetric properties of the photographic original as well as the transformation function of the scanner used. With this color transformation, the color space of the combination of actual type of original and scanner is imaged into a reference color space according to generally known methods, which corresponds to the level of quality of the processing photo lab. A true color digital image reproduction is achieved in this manner independent from the actual type of the original used and the actual type of scanner used, at a quality level which corresponds to the quality level of the photo lab. At the same time, the prerequisites are created for automatically maintenance of the color reproduction quality constant under all process constellations.

The invention also relates to a color measurement strip which is especially advantageous for the execution of the process.

### BRIEF DESCRIPTION OF THE DRAWINGS

The invention will be further described in the following by way of example only and with reference to the drawings, wherein:

FIG. 1 is a schematic, illustrating the set of problems underlying the present invention;

FIG. 2 is a principal schematic illustration of a preferred embodiment of the process in accordance with the invention;

FIG. 3 schematically illustrates the construction of a typical color measurement strip used for the process of the invention;

FIG. 4 is a principal schematic illustrating the creation of a profile; and

FIG. 5 is a principal schematic of a preferred embodiment of an apparatus in accordance with the invention.

### DETAILED DESCRIPTION OF THE PREFERRED EMBODIMENTS

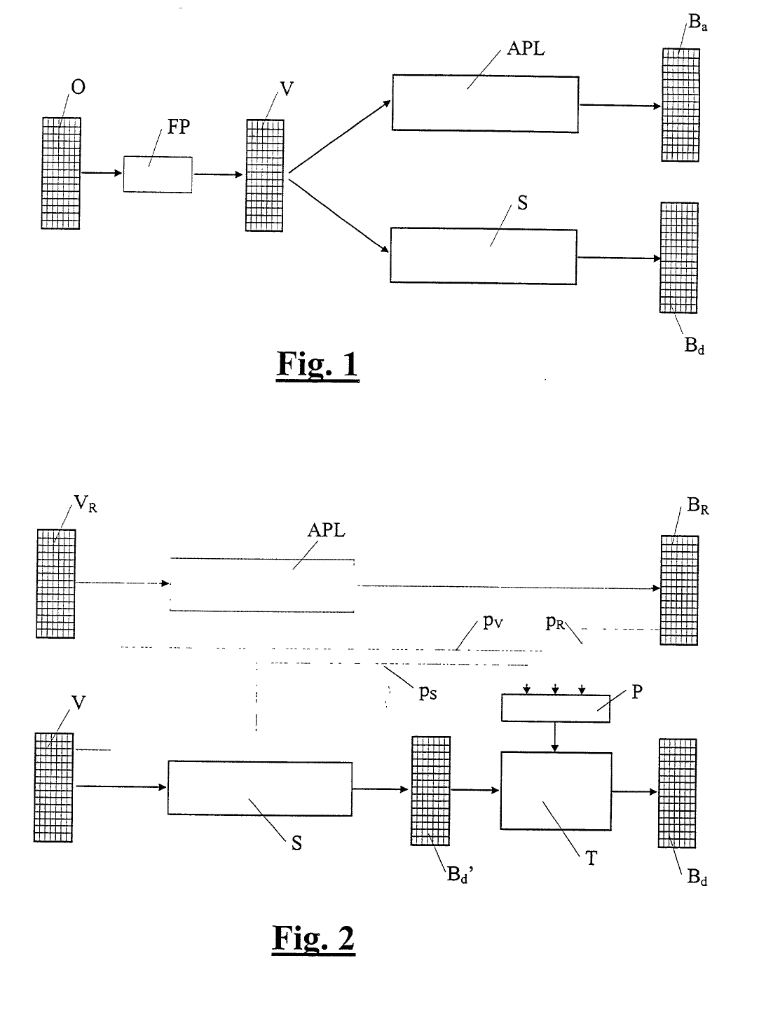

As is apparent from FIG. 1, an original image O is exposed onto a photographic color material and the latter treated in a conventional manner by wet chemistry in a film processor FP. The result is a color original V which includes an image motif corresponding to the original image and which forms the starting point for all downstream process steps. The original V is usually a photographic negative-film material, but a positive material can also be used. The originals of different materials occurring in the daily operation of a photo lab (different negative or positive film brands and film types) are generally referred to in the following as original types.

From the original V are now produced in the classical, analog manner a physical, analog color print (paper print) Bₐ and in a digital manner, a digital color picture B_{b}. A conventional analog production line APL is used for the manufacture of the analog color print Bₐ which includes, for example, a classical, photographic printer in combination with a suitable paper processor and is correspondingly calibrated. For the manufacture of the digital color picture B_{d}, a commercially available color-enabled high performance scanner S is used, which digitalizes the original by high resolution photoelectric scanning, possibly carries out an image conversion (negative to positive) and makes the digital photo B_{d} available in the form of a digital image file, for example in the well known JPEG format. Of course, if the original is a positive original, the image conversion is obviated.

As already mentioned above, the color impression of the analog color print Bₐ is generally significantly different from the one of the digital color picture B_{d} depending on the adjustment of the analog production line, the brand of scanner respectively used and the type of original used. Each original type has a specific spectral performance which in combination with the transfer function of the respectively used scanner can lead to different digital color pictures B_{d}, whereby the level of quality of the color representation is generally significantly lower than with classical analog color prints Bₐ.

In order to now achieve a digital color picture with a color quality which is largely independent from the original type and the brand or type of scanner, the principles of the color management are applied, according to the basic idea of the present invention, to the manufacturing process for the digital color photo, as illustrated in FIG. 2. In other words, the production process of the digital color picture is preferably incorporated with a color management system. For this purpose, the raw image data B_{d}′ produced by the scanning device or scanner S through digitization of the original V are subjected to a color transformation T, whereby the color space representable by the combination of the actual type of original and the actually used scanner is imaged onto the color space of a physical reference color print Bᵣ. The color transformation T generates the image data of the digital color picture B_{d} to be produced, which data are then stored for further conventional treatment (for example recording onto a data carrier medium and possibly a preceding image rotation or other image processing).

The reference color print Bᵣ is a physical, analog color print which was produced from an original of a selected type, referred to in the following as reference original type Vᵣ (“super-master”) and by way of a stabily operating analog production line APL normally used in the processing photo lab, and includes a number of color measurement fields. The original type preferably used as reference original type Vᵣ or super-master is the one processed most often in the respective photo lab. In this way, the reference color print Bᵣ represents the (internal, relative) level of quality of the respective photo lab (for analog color prints). However, another original type can of course also be used for these purposes.

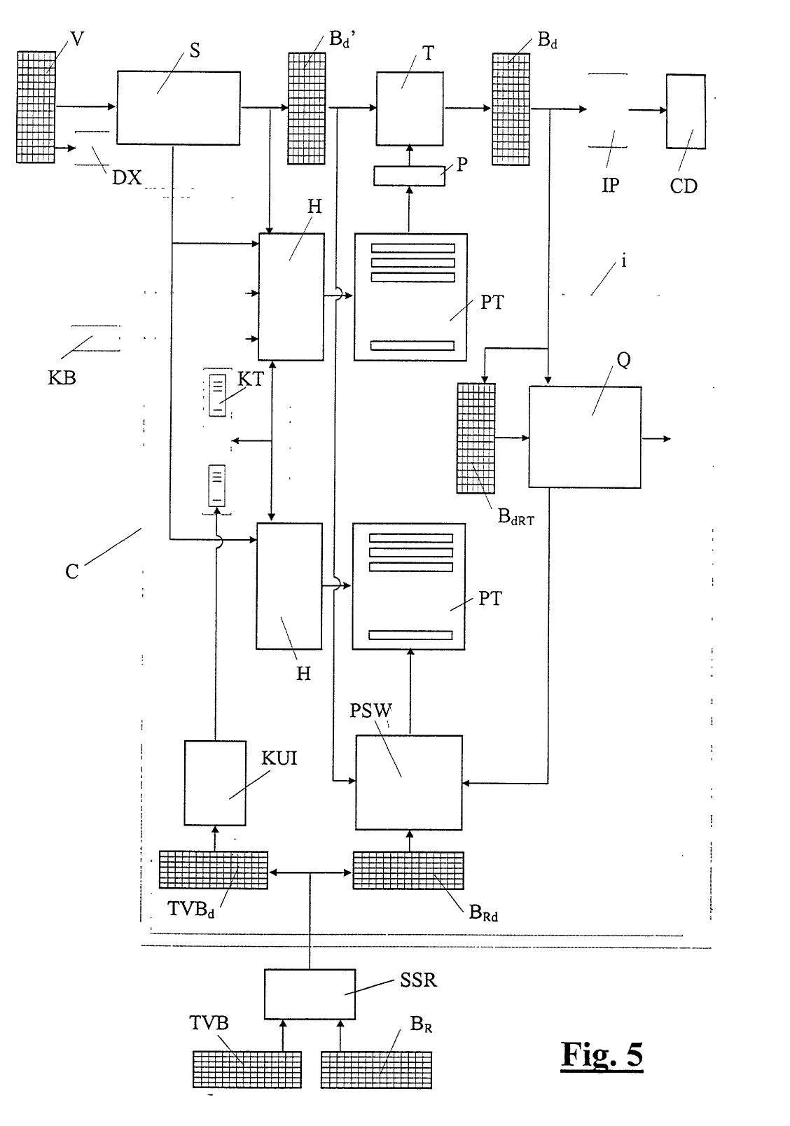

The color transformation T is carried out in a known manner by a standardized software module of a color management system. The required software is generally available and often even a component of computer operating systems (for example the color management module “ICM” forming part of the operating system MicroSoft Windows 2000). The transformation T requires as parameter a so called profile P, which includes information on the type specific calorimetric properties of the actual photographic original as well as the transfer function of the actually used scanning device (scanner). The profile P describes in a generally known original, standardized manner the color space encompassed by the combination of the actual original type V and the actually used scanner S and is specific for this combination, in that it associates the color values of this specific color space with absolute color values of the reference color print Bᵣ. Absolute color values can be, for example, sRGB or CIELab L*a*b* according to the specifications of the CIE (Commission Internationale de l'Eclairage). While the transformation algorithms of the transformation T are always the same for all possible combinations of master types and scanning devices, the transformation parameters respectively specific for each combination of original type and scanner type are found in this profile P. The linking of the profile P with the actual original V, the actual scanner S and the reference color print Bᵣ is symbolically illustrated in FIG. 2 by the broken lines pᵥ, pₛ and pᵣ. The generation of the profile P is described further below with reference to FIG. 4.

Color management and color management systems are generally known and are generally used in (other) digital color reproduction processes. A comprehensive and clear presentation of the background, technology and uses of color management systems is found in the publication “Postscriptum on Color Management, Philosophy and Technology of Color Management” by Stefan Brües, Liane May and Dietmar Fuchs, published in August, 1999, by the company Logo GmBH, a company of the Gretag MacBeth Group. A further article on color management is found, for example, in chapter 17 entitled “Device-Independent Color Imaging” of the book “Color Appearance Models” of Mark D. Fairchild, first edition, published 1997 by Addison Wesley. A further discussion of the color transformation T used in the process in accordance with the invention is therefore not necessary for the person skilled in the art.

By using the color transformation in accordance with the invention, the digital color picture B_{d} is always adapted to the color space of the reference color print Bᵣ independent of the respectively used original type and scanner type. The color impression of the digital color pictures produced in this way therefore mainly corresponds with the level of quality of the analog color prints manufactured in the respective photo lab, whereby the color quality of the digital color pictures always corresponds to the specific level of quality of the photo lab because of the specific selection of the reference color print. Strictly speaking, for each combination of original type and scanner brand (type) occurring in practice, an individual profile P should be created and used for the color transformation T in order to achieve an optimum color quality. However, with the large variety of the different original types (for example 50 and more) occurring in the everyday life of a photo lab and the not negligible number of simultaneously used different scanner types (for example 3 or more), at least in larger photo labs, this would very quickly lead to an extremely large number of required different profiles and would disproportionately drive up cost.

Thus, in accordance with a further aspect of the invention, a relatively small number of different profiles are used for the color transformation in order to keep the cost within bearable limits for the practical application. In order to make this possible without substantial quality losses which are unacceptable for the practical requirements, the original types occurring in practice are assigned to a relatively small number of original type categories according to similarity criteria to be described later, and a main original type (“master”) is set for each category. The master is thereby one of the original types belonging to the respective category and generally that original type which occurs most often within the category (in the respective photo lab). The following Table 1 illustrates by way of example how such a division into original type categories would appear in practice:

TABLE 1

| Category | Original type | Master Type | Reference Type |
|---|---|---|---|
| 1 | Optima 17-2 | Agfa 113-1 | Kodak 78-2 |
| | Agfa 113-1 | | |
| | Agfa 113-4 | | |
| 2 | Fuji 35-2 | Fuji 35-3 | |
| | Fuji 35-3 | | |
| 3 | Fuji 35-5 | Fuji 35-5 | |
| 4 | Kodak 78-3 | Kodak 78-2 | |
| | Kodak 78-2 | | |
| | Kodak 78-1 | | |

As is apparent, 9 different original types (in this example) are assigned to four different categories, which include 3, 2, 1 and 3 original types respectively. That original type which occurs in practice most often in each category is respectively fixed as the master type. The original type which overall occurs most often in the respective photo lab is then selected as the already above mentioned reference type (“super-master”). The individual assignment by the photo lab of the individual original types to the different categories of originals is recorded in a category table KT and stored.

A specific profile is created for all combinations of the scanners used in the processing photo lab with those master types, whereby those profiles associated with respectively one scanner type are recorded in a profile table PT associated with the respective scanner. If one assumes three different scanners, three profile tables with four different profiles each will result from the four categories in the above example.

During the manufacture of a digital color picture all original types within one category are considered equal in accordance with the invention and the color transformation for each original type in the category is carried out with the same profile, namely that profile which belongs to the scanner used and to the master type of the respective category. The costs are significantly reduced in this manner.

The assignment of the original types to the original categories depends in practice on the one hand on the principle type of original used (negative film, positive film . . . ) and on the other hand, on the quality required for the production process. In general, a more coarse categorization is possible for the lower quality requirements of amateur photography than for the high quality requirements of professional photography. Consequently, different original category tables KT are formed and stored in practice for the different constellations. It is thereby advantageous to hierarchically organize the production constellations possible in a photo lab during the production of digital color pictures, as schematically illustrated in the following Table 2:

TABLE 2

| Negative Film | | | Slide Film | | | Other Originals | | |
|---|---|---|---|---|---|---|---|---|
| Amateur | Professional | Others | Amateur | Professional | Others | Amateur | Professional | Others |
| KT₁₁ | KT₁₂ | KT₁₃ | KT₂₁ | KT₂₂ | KT₂₃ | KT₃₁ | KT₃₂ | KT₃₃ |

It is thereby differentiated at the uppermost level of hierarchy between the different starting materials (negative film, positive film, positive film, etc.) from which digital color pictures are to be produced. In the next lower level of hierarchy, one differentiates according to quality requirements, for example lower requirements for amateur photography and higher requirements for professional photography. The next level of hierarchy includes different category tables KTₘₙ for each possible combination of the selection possibilities of the two levels of hierarchy thereabove. For example, different category tables KT₁₁-KT₁₃ are provided in the above Table 2 for negative originals for amateur photography, professional photography and possibly other given demands. Of course, it is also possible under some circumstances to use the same category tables for different individual process constellations.

The category tables determined for each scanner S use the profiles to be selected for the respective process constellation depending on the actual original type. This is illustrated in the following Table 3:

TABLE 3

| | | | | | |
|---|---|---|---|---|---|
| S₁ | | KT₁ | . . . | KTₘ | |
| | | PT_{1,s1} | . . . | PT_{m,s1} | |
| | \| | | | | \| |
| | \| | | | | \| |
| S₂ | | KT₁ | . . . | KTₘ | |
| | | PT_{1,s2} | . . . | PT_{m,s2} | |

For each scanner S₁-S₂, a specific profile table PT_{1,s1}-PT_{n,si} and so on up to PT_{1,sz}-PT_{n,sz} belongs to each category table KT₁-KTₘ. The profile P corresponding to the actual original type is then selected from the profile table PT belonging to the actual scanner S by way of the actual category table KT belonging to the respective process constellation (copy negative, copy slide . . . ; amateur photography, professional photography . . . ). Of course, the stored profile SP and category tables KT are in practice preferably organized in a database format.

As already mentioned, the assignment of the individual original types to categories is carried out according to similarity criteria and normally by the processing photo lab, whereby original types with similar spectral properties are generally assigned to the same category. A practical possibility of the objective assignment is, for example, the use of suitable test images with test originals with color measuring fields of all original types to be categorized. The color values of the individual color measurement fields of the test original for each original type are thereby determined and compared with a corresponding color value of the color measuring fields of the other original types by way of a suitable, preferably automatic color measuring apparatus. Original types which lead to the same or similar color values within predetermined limits (criterion is sum or mean of the color deviations) are then assigned to one and the same category, while larger deviations respectively lead to a new category. The whole procedure is preferably software supported.

The creation of the profile P for the individual scanner-main master type-combinations is carried out in a generally known manner with the help of so called color measuring cards and with the use of a color measuring apparatus as well as commercially available profile generating software. The latter is sold, for example, under the name “Profile Maker” by the company Gretag-MacBeth AG, Regensdorf, Switzerland. Since color measuring cards used for profile generating purposes have a large number (several hundred) of color measuring fields, a scanning color measuring apparatus is preferably used for the colorimetric measuring which can automatically measure the whole color measuring card. An example of such a scanning color measuring apparatus is the spectral photometer “spectrolino” of the company Gretag-MacBeth in combination with the X/Y shifting table “spectroscan” of the same company. Alternatively, a conventional so called strip reader apparatus can be used having a color measuring head or a spectral measuring head and operating essentially like a feeder scanner.

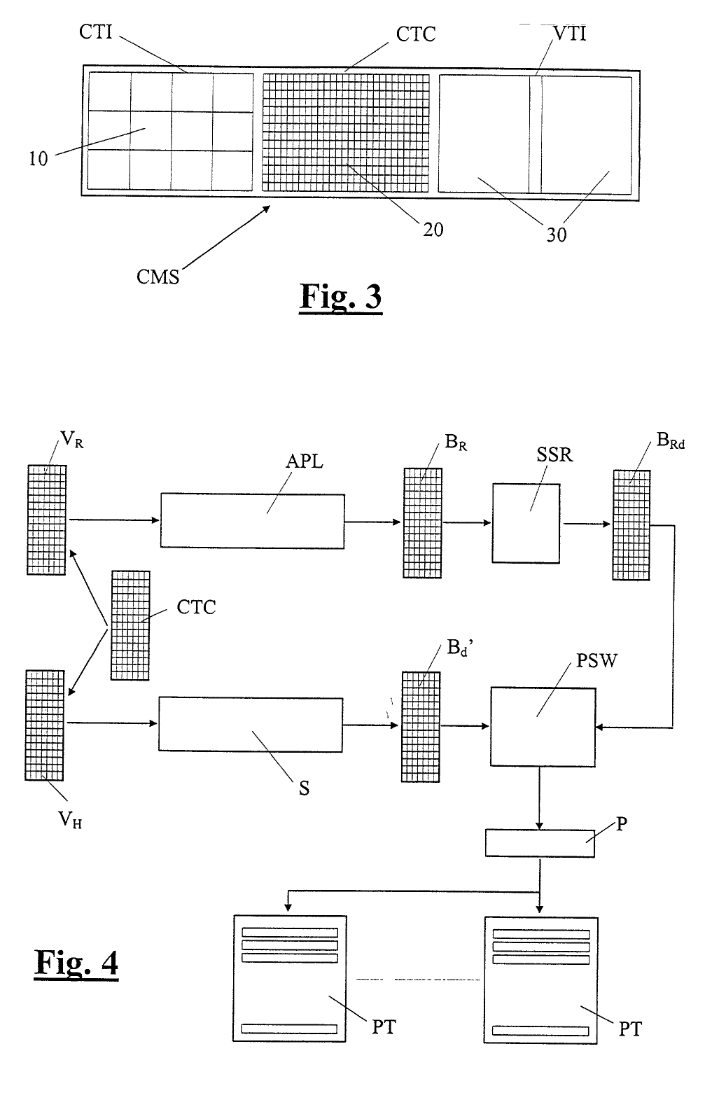

FIG. 3 shows the construction of a combined color measurement strip CMS which is especially suited for the purpose of the present invention and which essentially consists of three regions. A region CTI forms the already mentioned color test image for the categorization of the types of originals, the second region CTC forms a color test card for profiling purposes and a third region VTI includes, for example, two images 30 for the visual evaluation of the color pictures. The color test image region CTI includes, for example, 12 color measurement fields 10 in the form of 6 full tone fields of the additive and subtractive base colors, a white field, a black field and four grey fields of different density. The color test card region CTC includes in a known manner several hundred color measurement fields 20 of different color tones and densities. It is understood that the measurement field 20 of the color test card region CTC can also be used for the categorization of the types of originals; but the measurement and evaluation effort would thereby be significantly increased. It can also be mentioned anticipatory that the test image region CTI of the color measurement strip CMS can also be used for quality control in accordance with a further aspect of the invention; this will be discussed further below. Finally, the images 30 of the region VTI determined for the visual evaluation include in a generally known manner motives with critical color tones and color combinations, which are especially well suited for the visual evaluation. Suitable motives are known to a person skilled in the art.

By way of the color measurement strip CMS, physical test originals are formed in a known manner for all types of originals common in practice, in that the image information of the color measurement stip CMS is exposed from an original or digitally onto the individual original materials and the latter then developed in a standardized manner. The test originals carrying the color measurement strip as image information can be manufactured in the photo lab itself by way of a master color measurement strip or, for example, obtained from a professional enterprise specialized in the manufacture of such test originals.

According to a special embodiment of the process in accordance with the invention, at least the test image region CTI, but preferably also the other two regions CTC and VTI are exposed three times onto each type of original during the generation of the physical test original, particularly once with normal exposure, once with underexposure (for example, −2 apertures) and once with overexposure (for example, +2 apertures). This allows a more exact evaluation of the color quality and especially a more exact assignment during the above described categorization of the types of originals. 3×12 color values are now available per test original for comparison, instead of only 1×12 color values.

When the color values of the color measurement fields of the individual test originals intended for the categorization are determined and stored, they can be used for a later new categorization without one having to newly measure the test originals.

For a special embodiment of the invention, undeveloped test originals which carry the image information of the color measurement strip only in latent form can be required; this will be discussed further below.

For the generation of a profile for a specific combination of scanner-type and original type, as is schematically illustrated in FIG. 4, a test original of the reference type Vᵣ and a test original of the master type Vₕ to be profiled is made available, which both respectively carry (at least) the mentioned color measurement card CTC of the color measurement strip CMS as image information. A physical, analog reference color picture Bᵣ is then produced from the test original of the reference type Vᵣ by way of the analog production line APL, which picture includes the individual color measurement fields of the color measurement card CTC as image information. This analog reference color picture Bᵣ is then measured by way of a color measurement device, for example the mentioned spectral strip reader SSR, whereby the color value belonging to each color measurement field of the color test card is determined. The entirety of the color values determined in this way is symbolized in FIG. 4 by a digital reference image B_{rd}. A digital color picture B_{d}′ is produced from the test original of the master type Vₕ to be profiled by way of the scanner S to be profiled, but not color transformed. The (raw) image data of this digital color picture B_{d}′ in their entirety again represent the image information of the color measurement card CTC. The color values of the individual color measurement fields of the color measurement card from this digital color picture B_{d}′ and the measured color values of the corresponding color measurement fields of the color measurement card of the digital reference color picture B_{rd} are now fed to the above mentioned profile generating software PSW and the latter produces therefrom, in a generally known manner (for example, according to ICC), a standardized profile P for the given combination of original type and scanner. The profiles for all further original type-scanner combinations are produced in the same manner. The profiles P produced in this way are then grouped according to scanner type, filed in the profile tables PT belonging to the corresponding category tables KT, and assigned to the different scanners S, and are then available for the color transformation T in the manner already described above.

The generation of the profiles is practically carried out by way of a test original batch TVD. This is a physical collection of test originals of all different master types (“master”) relevant in practice. Such a test original batch includes per (master) original type, a color measurement strip CMS according to FIG. 3, preferably, as already mentioned, at three different exposure levels each.

According to a further important aspect of the invention, digital reference test color pictures B_{drt} are produced by way of the color transformation T and stored immediately after the generation and storage of all required profiles from the still stored raw image data B_{d}′ of the individual test originals present in the batch TVD by using the associated profiles just generated. They can, as will be explained further below, used for automatic quality control according to a further aspect of the invention.

FIG. 5 schematically illustrates the most important components of an exemplary embodiment of the apparatus in accordance with the invention. With the exception of the scanning device or scanner S and the strip reader SSR, all components of the apparatus are realized as functional modules of a software package running on a computer. Therefore, for a more convenient correlation of the individual components of the apparatus, the same reference numbers are used in FIG. 5 as for the corresponding process steps or functions of the process illustrated in FIGS. 2 to 4. It is readily apparent that in practice a computer system or computer network can be, and typically is, provided instead of a single computer. It is important only that all the digital cycles and functions described in the following are in their entirety somehow implemented centrally or decentralized.

The preferred illustrated apparatus in accordance with the invention for the manufacture of digital color pictures includes as most important components the scanning device or scanner S and a computer or computer network C as well as the color measurement device SSR which is preferably a spectrally operating strip reader device. The computer C includes a conventional keyboard KB as well as a monitor which is not illustrated. Furthermore, a DX-code reader DX is provided. The scanning device S, the color measurement device SSR and the DX-code reader DX are connected to the computer C in a generally known manner and also communicate therewith and are controlled thereby in a known manner. So far, the apparatus in accordance with the invention corresponds to the prior art so that the person skilled in the art does not require any further guidance in this respect. The components of the apparatus in accordance with the invention, which are different from the prior art, are framed by the broken line i.

The computer C includes a series of specific input handlers H which are respectively assigned to one of the different types of scanners S used in the photo lab. The input handlers H monitor their associated scanner S and recognize when a scanner is active and produces digital image data from an original V. The input handlers H cooperate with the previously produced and stored category tables KT and the also stored profile tables PT. They recognize the type of original being processed by way of the accompanying data (for example a so called capture file) which are typically made available by high performance scanners used for these purposes. If the scanner type does not produce such accompanying data, the type of original can be determined by way of the DX code reader DX and transmitted to the input handler H. Finally, a manual input by way of the keyboard KB is also possible, for example, for slide originals. The category tables KT and the associated profile tables PT for the specific process constellations (negative copy, slide copy, . . . ; amateur photography, professional photography, . . . , compare description further above) are defined in the adjustments of the input handlers H. On the basis of the actual original type, the master type of the respective original category is then determined and a profile P to be used on the basis of the master type is made available from the profile table PT to the color management module (transformation module) T. The latter transforms the raw image data B_{d}′ produced by the scanners by using the profile P selected by the input handler H and produces therefrom the image data of the transformed digital color picture B_{d}. The digital image is now rotated, if required, in a picture rotation unit IP in a conventional and known manner, and then stored in the file system of the computer C at a location suited for further processing. The stored or fully processed digital color pictures can then be recorded, for example by way of a recording software CD in a generally known manner on a data carrier, for example a compact disk. All the additional image processing procedures which are applied to conventionally produced digital color pictures normally after the digitization can also be applied to the digital color picture transformed in accordance with the invention.

The computer or computer network C also includes a generally known profile generation module PSW which cooperates in the manner described above in connection with FIG. 4, the connected automatic color measuring apparatus SSR, as well as with the scanner or scanners S, and produces the profiles P for each combination of scanner type and master type and files it in the profile table PT associated with the respective scanner type. The profile production is carried out in the previously described manner by way of the test original batch TVB including all master types. After the profile generation, the digital reference test color pictures B_{drt} are also produced and stored at a suitable location in the file system of the computer C.

Furthermore, a categorizing module KUI is provided, which screen-guided and interactively supports the user in the formation of the category tables and the assignment of the different types of originals to original categories. It thereby compares in the above described manner the color values of the color measurement fields on the test originals read-in by way of the strip reader SSR or other color measurement apparatus and fully automatically produces therefrom the category tables KT according to an allocation strategy selected by the user (for example maximum color deviation, number of categories) and stores the tables. The entirety of the color values of the test original batch TVB measured by way of the strip reader SSR and stored for further usage is symbolically identified as TVD_{d} in FIG. 5.

According to a further important aspect, a quality monitoring module Q is also provided. This compares actually produced digital test color pictures B_{dt} with the previously stored test color pictures B_{drt} and signalizes deviations in a format common in process monitoring systems, for example on the monitor connected to the computer C. Two limits are thereby preferably provided. For example, when a first deviation limit is surpassed, a corresponding warning message can be produced, upon crossing of a second deviation limit, for example, a new profiling can be initiated or the production process stopped. For the practical realization of the quality monitoring, the test original batch TVB is fed into the production process from time to time, for example 3-4 times daily and the digital test color pictures produced from this test original batch compared with the corresponding reference test color pictures B_{drt}. The color test image region of the color measurement strip with a relatively few (in the example 12) color measurement fields is preferably used for this comparison. The comparison criterion can be, for example, the sum or the average of the color deviations of the individual color measurement fields.

Undesired changes in the color reproduction quality caused especially by changes of the scanners S used can be recognized early by regular quality monitoring and corresponding correction measures can be initiated, especially automatically. For example, the quality monitoring module Q can initiate a new calculation of some, or in the extreme case, of all profiles P. Since the test originals of the test original batch also include the color test cards, all measurement values required for the new calculation of the profiles are always automatically present during the quality control.

When the digital color pictures are not produced from fully developed but from undeveloped originals, the quality monitoring can be expanded according to a further aspect of the invention to include the wet chemistry process (film development FP) used during the manufacture of the original V. In that case, the previously mentioned undeveloped test originals are used. When the profiles are also generated from undeveloped test originals carrying latent test images, they furthermore include even the influences of the wet chemistry treatment of the original material. In this manner, the color quality of the digital color pictures can also be made independent (within limits) from the specific wet chemistry treatment of the material of the original.

By way of the invention it is for the first time practically possible to use color management in the production of digital color pictures and to thereby achieve a consistent color reproduction quality for all process constellations.

1. Process for the manufacture of a digital color picture from an original, comprising the steps of photoelectrically scanning the original by way of a color-enabled scanning device for obtaining scanning data, forming the digital color picture from the scanning data, transforming the digital color picture by way of a color transformation for achieving a colorimetric correspondence between the digital color picture and a reference color test picture, and one of storing the transformed digital color picture in a preselected format and recording the digital color picture on a data carrier medium.

2. Process according to claim 1, wherein the steps of transforming are carried out according to color management principles by using a specific profile which describes the combination of the type-specific colorimetric properties of the original and the specific transfer function of the scanning device.

3. Process according to claim 2, comprising the further step of providing a profile for each of a number of combinations of different original types and different scanning devices, and wherein the step of transforming is carried out with that profile which belongs to the actually used scanning device and the actual original type used.

4. Process according to claim 3, wherein the step of providing the profile includes the steps of respectively assigning the different original types according to similarities in colorimetric properties to one of a number of original categories, setting one original type for each original category as master original, providing a separate profile for each combination of master original and different scanning device, and wherein the step of transforming is carried out with that profile which belongs to the actually used scanning device and to that master original which belongs to the original category to which the actual photographic original belongs.

5. Process according to claim 4, wherein different assignments of original types to the original categories are formed for different quality requirements and used for the selection of the respective profile.

6. Process according to claim 3, including the further steps of providing test originals of the individual original types for the assignment of the different original types to the original categories, the test originals carrying a test image having several color measurement fields measuring the color values of the color measurement fields, comparing the color measurement data of the test originals and assigning the original types based on the comparison of the color measurement values.

7. Process according to claim 1, comprising the further steps of selecting one original type as superior reference original type, making a physical analog color test card as reference color test image from an original of the reference original type, the test card including a color measurement card, and using this reference color test image for creating the profile.

8. Process according to claim 2, including the further steps of carrying out a quality control from time to time using the test originals, by calorimetrically comparing digital test color pictures produced from the test originals with corresponding reference test color pictures, determining a quality measurement from the color differences, and newly creating the profiles when the quality measurement exceeds a preselected threshold value.

9. Process according to claim 2, including the steps of treating the original which is an exposed photographic original material, by wet chemistry prior to the scanning, and incorporating the wet chemistry treatment of the original material into the formation of the profile.

10. Apparatus for the manufacture of a digital color picture, comprising a color-enabled scanning device for photoelectrically scanning the original to obtain scanning data and a computer for forming the digital color picture from the scanning data obtained in a preselected data format, the computer cooperating with the scanning device and storing the digital color picture and recording it on a data carrier medium, the computer subjecting the digital color picture prior to the storage or recording to a color transformation for transforming the color space defined by the combination of the type specific colorimetric properties of the original and the specific transfer function of the scanning device used, so that a colorimetric correspondence between the digital color picture and a reference color test picture is achieved.

11. Apparatus according to claim 10, wherein the computer is constructed for carrying out the color transformation according to color management principles by using a specific profile which describes the combination of the type specific colorimetric properties of the original and the specific transfer function of the scanning device used.

12. Apparatus according to claim 11, wherein the computer comprises means for respectively storing one profile for one of a number of combinations of different types of originals with different scanning devices, means for recognizing the actually used scanning device and the type of the actual original on the basis of information in relation thereto, whereby the computer is constructed for carrying out the transformation with that profile which belongs to the actually used scanning device and the actual original type.

13. Apparatus according to claim 12, wherein the computer further comprises means for respectively assigning each of a number of different original types according to similarities of the spectral properties to one of a number of original categories and for selecting one type of original category for each original as master original means for storing a profile for each combination of master original and one of a number of different scanning devices, and whereby the computer is constructed for carrying out the color transformation with that profile which actually belongs to the actually used scanning device and to the master original of that original category to which the actual photographic original belongs.

14. Apparatus according to claim 11, wherein the computer includes a profile generation means for automatically creating a profile on the basis of image data of a digital test color picture and a reference color test picture.

15. Apparatus according to claim 10, further comprising quality control means for controlling the quality of the digital color picture.

16. Apparatus according to claim 15, the quality control means forming a quality measure by comparing digital test color pictures with corresponding digital reference test color pictures and causing a new calculation of the profile when the quality measure exceeds a preselected threshold value.

17. A color measurement strip for carrying out a process according to one of claims 1-9, comprising a color test image region with a relatively small number of color measurement fields, a color test card region with a relatively large number of color measurement fields and a visual test image region with at least one picture motif suitable for a visual color evaluation.

18. Color measurement strip according to claim 17, wherein the color test image region includes 12 color measurement fields in the additive and subtractive base colors, white, black and four different shades of gray respectively.
